(19) United States
(12) Patent Application Publication
(10) Pub. No.: US 2014/0049935 A1
(43) Pub. Date: Feb. 20, 2014

(54) SHIELDING CAN ASSEMBLY

(71) Applicant: Wistron Corporation, New Taipei City (TW)

(72) Inventors: HUNG-SHENG CHEN, New Taipei City (TW); JIAN-SHIANG JUANG, New Taipei City (TW)

(21) Appl. No.: 13/939,778

(22) Filed: Jul. 11, 2013

(30) Foreign Application Priority Data
Aug. 16, 2012 (TW) 101129800

(51) Int. Cl. H05K 9/00

(52) U.S. Cl. CPC H05K 9/0033
USPC 361/818

(57) ABSTRACT

A shielding can assembly connected to a circuit board for eliminating electromagnetic interference is disclosed, wherein the circuit board has at least one hole. The shielding can assembly has a cover and an assemble element. The cover is situated at a side of the circuit board; the assemble element with at least one assemble portion is situated at another side of the circuit board. The at least one assemble portion passes through the at least one hole to connect with the cover such that the circuit board is situated between the cover and the assemble element.

### BACKGROUND OF THE INVENTION

1. Field of the Invention

The present invention relates to a shielding can assembly.

2. Description of the Related Art

Circuit boards, conducting wires and electronic components in an electronic device would generate high-frequency electromagnetic waves during operations, and thus cause electromagnetic interference (EMI) to normal tasks of the electronic device. In order to reduce the EMI, conventionally a shielding can is utilized to cover the circuit board, conducting wire and electronic component therein, so as to shield the electromagnetic waves. However, the shielding can is usually welded to the circuit board, if the electronic component covered by the shielding can needs to be replaced or fixed, the shielding can needs to be cut out directly or melted so as to detach the shielding can from the circuit board. Nevertheless, either of the abovementioned detachment methods would cause damage to the shielding can and make it non-reusable, which is bad for saving maintenance cost; moreover, the action force applied to the circuit board during the process of detaching the shielding can would easily cause damage to the structure of the circuit board and the electronic component.

Besides the technique of welding the shielding can to the circuit board, conventionally another type of mounting device is provided for being directly welded to the circuit board, so as to connect to the shielding can for mounting the shielding can to the circuit board. However, take current commonly-implemented surface-mount technology (SMT) as an example, when the mounting device is welded to the circuit board, there would be an error of about 0.05 mm to 0.1 mm of the position of the mounting device; therefore, if multiple mounting devices need to be welded linearly, the position error of the mounting device would increase accordingly, which may lower the production yield rate and cause trouble to assembly without conforming to economic efficiency.

Therefore, there is a need to provide a shielding can assembly which is easy to assemble/disassemble, reusable and has a higher production yield rate to mitigate and/or obviate the aforementioned problems.

### SUMMARY OF THE INVENTION

It is an object of the present invention to provide shielding can assembly.

To achieve the abovementioned object, the shielding can assembly of the present invention is connected to a circuit board, and is used for eliminating electromagnetic interference of an electronic component on the circuit board. The circuit board has at least one hole. The shielding can assembly comprises a cover and an assemble element. The cover is situated at one side of the circuit board, and comprises a cover plate and at least one assemble wall, wherein the at least one assemble wall is connected to the cover plate. The assemble element is situated at another side of the circuit board, and comprises at least one assemble portion, wherein the at least one assemble portion passes through the at least one hole to connect with the at least one assemble wall, such that the circuit board is situated between the cover and the assemble element.

According to one embodiment of the present invention, the at least one assemble portion further comprises two assemble pieces, and an assemble slot is formed between the two assemble pieces for the at least one assemble wall to be engaged and inserted therein. Further, the two assemble pieces are parallel to each other.

According to one embodiment of the present invention, the two assemble pieces are parallel to each other and are arranged in right-left staggered positions.

According to one embodiment of the present invention, the at least one assemble portion comprises a plurality of assemble portions, and the at least one assemble wall comprises a plurality of assemble walls, such that the plurality of assemble portions are engaged with the plurality of assemble walls.

According to one embodiment of the present invention, the at least one assemble wall is at least engaged with two adjacent assemble portions.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates a structural exploded view of a shielding can assembly and a circuit board according to one embodiment of the present invention.

FIG. 2 illustrates an enlarged partial view of a cover and an assemble component according to one embodiment of the present invention.

FIG. 2A illustrates a cross sectional view of FIG. 2.

FIG. 3 illustrates an enlarged partial view of the cover and the assemble component according to another embodiment of the present invention.

FIG. 3A illustrates a cross sectional view of FIG. 3.

### DETAILED DESCRIPTION OF THE PREFERRED EMBODIMENT

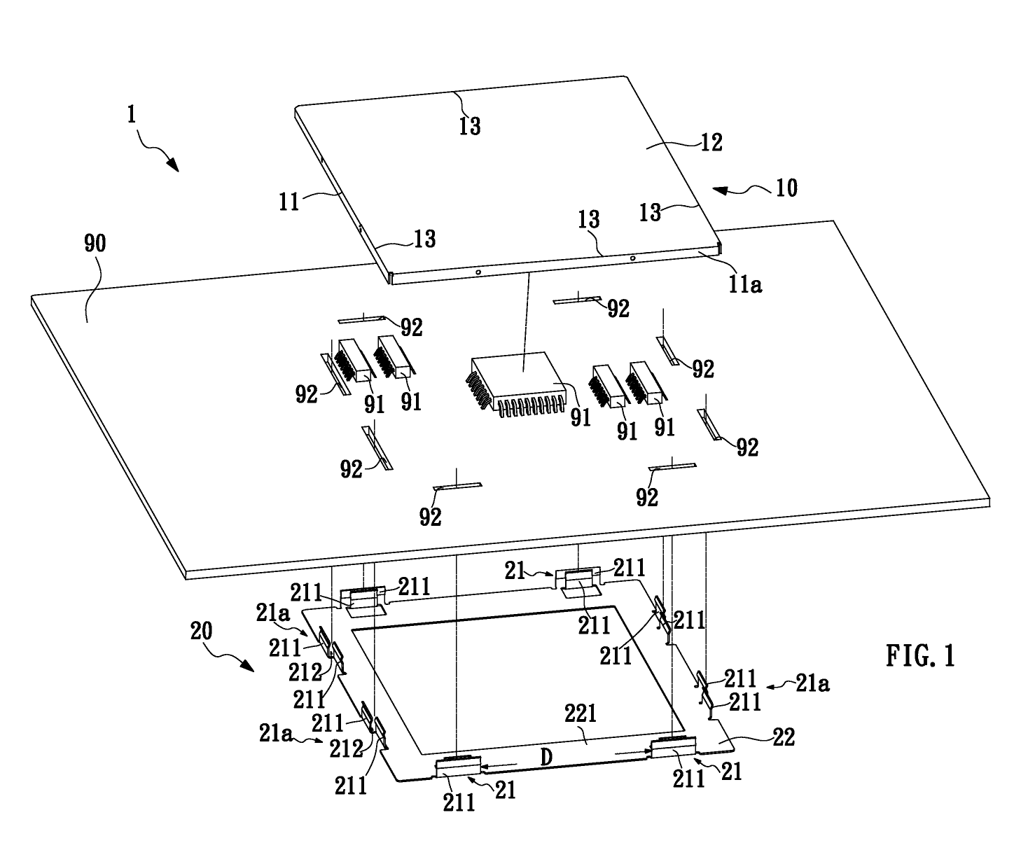

Please refer to FIG. 1, which illustrates a structural exploded view of a shielding can assembly and a circuit board according to one embodiment of the present invention. As shown in FIG. 1, the shielding can assembly 1 of the present invention is connected to a circuit board 90, and is used for eliminating electromagnetic interference generated during operations of electronic components 91 installed on the circuit board 90.

The shielding can assembly 1 of the present invention comprises a cover 10 and an assemble element 20. As shown in FIG. 1, the cover 10 is made of metal, so as to eliminate the electromagnetic interference generated during operations of the electronic components 91. The cover 10 comprises assemble walls 11 and a cover plate 12. In this embodiment, the cover 10 comprises four assemble walls 11 (FIG. 1 only illustrates the assemble wall 11 and the assemble wall 11a). The cover plate 12 is rectangular-shaped, and each of the assemble walls 11 is respectively connected to each of four side edges 13 (as shown in FIG. 1) of the cover plate 12. Please note that the scope of the present invention is not limited to the above description. For example, the shape of the cover plate 12 can be designed according to the shape of the circuit board 90 or the surface area of the electronic element 91 to be covered. Furthermore, no matter what shape of the cover plate 12 is, the assemble wall 11 does not need to be connected to each side edge of the cover plate 12.

The assemble element 20 comprises at least one assemble portion 21 and a connection plate 22. The assemble portion 21 further comprises two assemble pieces 211, and an assemble slot 212 is formed between the two assemble pieces 211 for the assemble wall 11 to be engaged and inserted therein. As shown in FIG. 1, in this embodiment, the assemble element 20 comprises eight assemble portions 21. The connection plate 22 of this embodiment comprises a first connection plate side edge 221, wherein the first connection plate side edge 221 is provided with two assemble portions 21, and the assemble wall 11a is connected to the two assemble portions 21 at the same time. Further, the other six assemble portions 21 are respectively disposed to the other three connection plate side edges of the connection plate 22. Please note that the connection plate 22 and the assemble portion 21 are formed and combined in one piece, and the assemble portion 21 is disposed to the side edge of the connection plate 22 (such as the first connection plate side edge 221 or other side edges). The advantages for not directly welding the assemble portion 21 onto the circuit board 90 include:

1. The assemble element 20 can be manufactured by a single mold so as to save the manufacturing cost;

2. To guarantee that the linear error between each of the assemble portions 21 disposed to the same side edge is smaller than or equal to 0.05 mm, such that the linearity of each assemble portion 21 on the same side edge is improved, and thus the assemble wall 11a can be precisely inserted into respective assemble portions 21 on the same side edge at the same time (as shown in FIG. 1), so as to increase the production yield rate.

Further, as shown in FIG. 1, according to the characteristic of the improved linearity of the assemble portions 21 on the same side edge, the distance between adjacent assemble portions 21 on the same side edge can be increased. In this embodiment, the distance D between two adjacent assemble portions 21 on the first connection plate side edge 221 is, but not limited to, 20 mm. Moreover, the distance D between two adjacent assemble portions 21 on the same side edge can be adjusted by the user. As a non-limiting example, the distance D for keeping the cover 10 and the assemble element 20 under a stable assembly state is about 30 mm to 35 mm. The user can flexibly adjust the distance between two adjacent assemble portions 21 on the same side edge of the cover 10 according to practical scenarios, as well as the number of the assemble portions 21 on the same side edge of the cover 10. Please note that if the overall length and width of the cover 10 and the assemble element 20 are relatively small, the number of the assemble portions 21 on the single side edge of the cover 10 can be odd.

In this embodiment, as shown in FIG. 1, the cover 10 is disposed above the circuit board 90, and the assemble element 20 is disposed underneath the circuit board 90. Therefore, when the cover 10 and the assemble element 20 are connected to each other, the eight assemble portions 21 of the assemble element 20 would respectively pass through corresponding holes 92 of the circuit board 90 for being connected to the assemble walls 11 of the cover 10. Please note that in order to match the eight assemble portions 21 of this embodiment, the circuit board 90 of this embodiment has eight holes 92 located corresponding to respective assemble portions 21, such that the assemble portions 21 can respectively pass through the corresponding holes 92. Please note that the cover 10, the assemble element 20 and the circuit board 90 do not have a specific arrangement relationship, it is applicable as long as the circuit board 90 is situated between the cover 10 and the assemble element 20, and the electronic component 91 is covered within the cover 10.

Because the connection type of the shielding can assembly 1 of the present invention is to engage the cover 10 and the assemble element 20 with each other instead of directly welding the cover 10 or the assemble portion 21 of the assemble element 20 directly onto the circuit board 90, the cover 10 does not need to be taken apart for fixing or replacing the electronic element 91 installed on the circuit board 90, and there is no need to break the soldering tin between the assemble portion 21 of the assemble element 20 and the circuit board 90. The maintenance personnel only needs to detach the cover 10 from the assemble element 20 so as to reduce the damage caused to the cover 10 itself or the circuit board 90. After the maintenance process, the maintenance personnel only needs to re-engage the assemble wall 11 of the cover 10 with the assemble slot 212 of the assemble element 20 to mount the shielding can assembly 1. Because the cover 10 is not damaged, the shielding can assembly 1 of the present invention is made reusable, so as to solve the problems such as the conventional cover cannot be reused, is difficult to be detached, and is easy to be damaged during the detaching process.

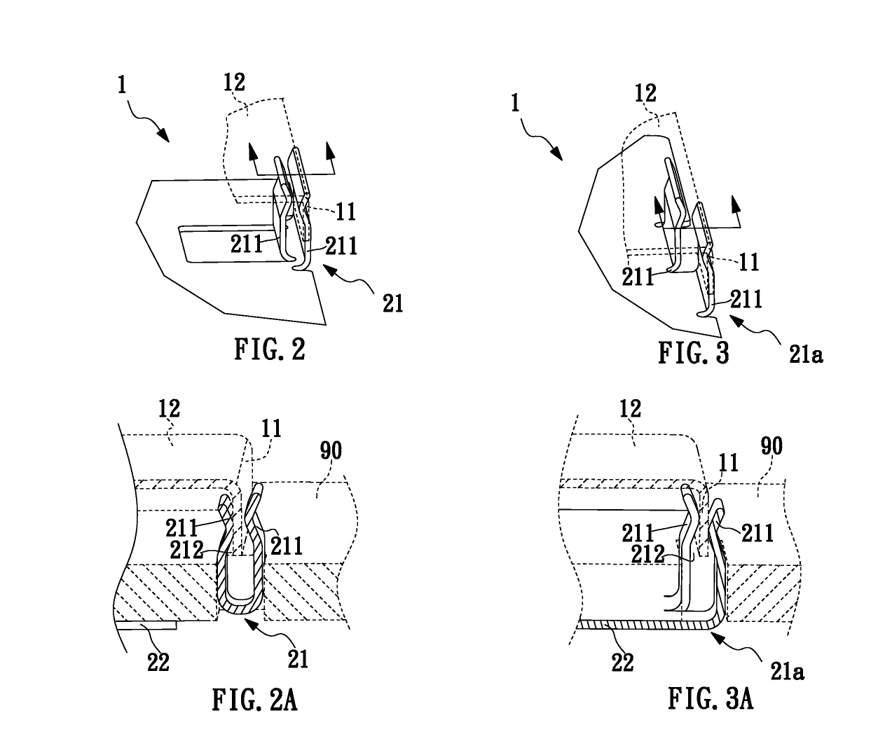

Further, as shown in FIG. 1, the assemble portion 21 of the present invention can be implemented as two embodiments according to corresponding position relationships of the two assemble pieces 211, such as the assemble portion 21 (parallel type) and the assemble portion 21a (staggered type). Please refer to FIG. 2, FIG. 2A, FIG. 3 and FIG. 3A for more details about the characteristics of these two embodiments, wherein FIG. 2 illustrates an enlarged partial view of the cover and the assemble component according to one embodiment of the present invention; FIG. 2A is a cross sectional view of FIG. 2; FIG. 3 illustrates an enlarged partial view of the cover and the assemble component according to another embodiment of the present invention; and FIG. 3A is a cross sectional view of FIG. 3.

As shown in FIG. 2, the first embodiment of the assemble portion 21 is that the two assemble pieces 211 are parallel to each other, wherein the gap between the two parallel assemble pieces 211 forms the assemble slot 212 for the assemble wall 11 to be engaged and inserted therein. According to FIG. 2A, after the assemble wall 11 is inserted into the assemble slot 212, the circuit board 90 is situated between the cover plate 12 and the connection plate 22.

As shown in FIG. 3, the second embodiment of the assemble portion 21a is that the two assemble pieces 211 are parallel to each other, and are further arranged in right-left staggered positions. Because the two assemble pieces 211 are arranged in right-left staggered positions, the gap between the two assemble pieces 211 forms the assemble slot 212 for the assemble wall 11 to be engaged and inserted therein. According to FIG. 3A, after the assemble wall 11 is inserted into the assemble slot 212, the circuit board 90 is situated between the cover plate 12 and the connection plate 22.

Although the present invention has been explained in relation to its preferred embodiments, it is to be understood that many other possible modifications and variations can be made without departing from the spirit and scope of the invention as hereinafter claimed.

What is claimed is:

1. A shielding can assembly, connected to a circuit board, used for eliminating electromagnetic interference of an electronic component on the circuit board, wherein the circuit board has at least one hole, the shielding can assembly comprising:
a cover, situated at one side of the circuit board, the cover comprising a cover plate and at least one assemble wall, wherein the at least one assemble wall is connected to the cover plate; and
an assemble element, situated at another side of the circuit board, the assemble element comprising at least one assemble portion passing through the at least one hole to connect with the at least one assemble wall, such that the circuit board is situated between the cover and the assemble element.

2. The shielding can assembly as claimed in claim 1, wherein the at least one assemble portion further comprises two assemble pieces, and an assemble slot is formed between the two assemble pieces for the at least one assemble wall to be engaged and inserted therein.

3. The shielding can assembly as claimed in claim 2, wherein the two assemble pieces are parallel to each other.

4. The shielding can assembly as claimed in claim 3, wherein the two assemble pieces are arranged in right-left staggered positions.

5. The shielding can assembly as claimed in claim 4, wherein the at least one assemble portion comprises a plurality of assemble portions, and the at least one assemble wall comprises a plurality of assemble walls, such that the plurality of assemble portions are engaged with the plurality of assemble walls.

6. The shielding can assembly as claimed in claim 5, wherein the at least one assemble wall is at least engaged with two adjacent assemble portions.

7. The shielding can assembly as claimed in claim 2, wherein the at least one assemble portion comprises a plurality of assemble portions, and the at least one assemble wall comprises a plurality of assemble walls, such that the plurality of assemble portions are engaged with the plurality of assemble walls.

8. The shielding can assembly as claimed in claim 7, wherein the at least one assemble wall is at least engaged with two adjacent assemble portions.
